(19) United States
(12) Patent Application Publication
(10) Pub. No.: US 2011/0249510 A1
(43) Pub. Date: Oct. 13, 2011

(54) EMBEDDED STORAGE APPARATUS AND TEST METHOD THEREOF

(75) Inventors: Nien-Tsung Hsueh, Hsinchu County (TW); Jin-Sheng Hsieh, Hsinchu County (TW); Chun-Hung Chen, Yunlin County (TW)

(73) Assignee: NOVATEK MICROELECTRONICS CORP., Hsinchu (TW)

(21) Appl. No.: 13/076,444

(22) Filed: Mar. 31, 2011

(30) Foreign Application Priority Data
Apr. 13, 2010 (TW) 99111441

(51) Int. Cl. G11C 7/10; G11C 29/00; G11C 7/00

(52) U.S. Cl. 365/189.02; 365/191; 365/201

(57) ABSTRACT

An embedded storage apparatus including a control unit, a storage unit, and a signal processing and measurement unit is provided. The control unit outputs a plurality of signals, wherein the signals include a mode selection signal and a plurality of control signals. The storage unit is controlled by the control unit to read a data from a predetermined address. The storage unit has a plurality of output terminals. The signal processing and measurement unit has a plurality of input terminals and a plurality of output terminals, wherein the input terminals are connected to the output terminals of the storage unit. The signal processing and measurement unit reads the data from the output terminals and determines whether to perform a predetermined processing on the data according to the mode selection signal. After that, the signal processing and measurement unit outputs the data through the output terminals.

### CROSS-REFERENCE TO RELATED APPLICATION

This application claims the priority benefit of Taiwan application serial no. 99111441, filed Apr. 13, 2010. The entirety of the above-mentioned patent application is hereby incorporated by reference herein and made a part of this specification.

### BACKGROUND OF THE INVENTION

1. Field of the Invention

The present invention generally relates to an embedded storage apparatus, and more particularly, to an embedded storage apparatus with different data output channels and improved test procedure.

2. Description of Related Art

In the conventional design of embedded storage apparatus, the time for writing and reading data is usually planned differently. This is because the driving capability of the data lines is much higher than the loads of the bit lines and the memory cells when data is written into a storage apparatus. Thus, during a data writing period, the data is directly written into the memory cells through the bit lines and the data lines in a short time. However, during a data reading period, data in the memory cells is first transmitted to the bit lines and the data lines after the bit lines and the data lines are pre-charged by a storage unit. When the voltage level on the data lines is pulled up, the small voltage difference is amplified by a sense amplifier. Eventually, the data is read from the memory cells through a data bus. Such a data reading procedure is very time-consuming and complicated, and accordingly it takes much longer time to read data from the storage apparatus than to write data into the same.

Memory capacity has always been demanded more when the chip system is developed in more complicate. It takes most of the testing time of a chip system to test an embedded storage apparatus if the data reading time is not shortened. Thus, the problem of how to effectively shorten the data reading time of a storage apparatus and accordingly speed up the subsequent testing procedure is to be resolved with the increasing memory capacity.

In a conventional technique of testing an embedded storage apparatus, data is read from the storage apparatus by a control device through a data bus having a width of one word, so as to determine whether the entire storage apparatus is read or written properly. In this technique, an address of the storage apparatus has to be preset and data is read from the address of the storage apparatus by the control device. Such a one-on-one data reading technique prolongs the time for reading the storage apparatus and accordingly results in extra testing cost. Particularly, this technique is not applicable to those large-capacity systems.

Thereby, the testing mechanism of embedded storage apparatus is to be further developed.

### SUMMARY OF THE INVENTION

Accordingly, the present invention is directed to an embedded storage apparatus, wherein at least a faster measurement technique is achieved during a testing procedure of the embedded storage apparatus.

The present invention provides an embedded storage apparatus including a control unit, a storage unit, and a signal processing and measurement unit. The control unit outputs a plurality of signals, wherein the signals include a mode selection signal and a plurality of control signals. The storage unit is controlled by the control unit to read a data from a predetermined address. The storage unit has a plurality of output terminals. The signal processing and measurement unit has a plurality of input terminals and a plurality of output terminals, wherein the input terminals are connected to the output terminals of the storage unit. The signal processing and measurement unit reads the data from the input terminals and determines whether to perform a predetermined processing on the data according to the mode selection signal. After that, the signal processing and measurement unit outputs the data through the output terminals.

The present invention provides a test method adaptable to the embedded storage apparatus described above. In the present test method, a test data is written from the control unit into the storage unit. In addition, the mode selection signal is activated to directly output the test data through the output terminals, wherein the test data is transmitted to an output port by the signal processing and measurement unit.

The present invention provides a test method adaptable to an embedded storage apparatus. The embedded storage apparatus includes a storage unit and a signal processing unit, wherein the storage unit has a plurality of output terminals. In a regular operation mode, the signal processing unit processes a data output by the storage unit and outputs the processed data through an output port. In the present test method, a test data is written into the storage unit, and the unprocessed test data is directly output through the output port via an output path of the signal processing unit.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an embedded storage apparatus according to an embodiment of the present invention.

FIG. 2 is a circuit diagram of a signal processing and measurement device according to an embodiment of the present invention.

FIG. 3 is a schematic diagram of an embedded storage apparatus according to another embodiment of the present invention.

FIG. 4 is a circuit diagram of a signal processing and measurement device according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In an embedded storage apparatus provided by the present invention, the many existing I/O ports of a chip system are served as a read-back path of a storage device, so as to achieve a fast measurement effect. Below, embodiments of the present invention will be described. However, these embodiments are not intended to limit the scope of the present invention and may be combined appropriately.

Along with the advancement of fabrication processes, the number of transistors disposed within each unit area has been increasing, and the circuit realized has been getting more and more complicated. Thus, an increasing number of circuits have been packaged inside chips, and the storage capacity has been increased constantly. Accordingly, embedded memory has gradually replaced the conventional stand alone chip as the mainstream design.

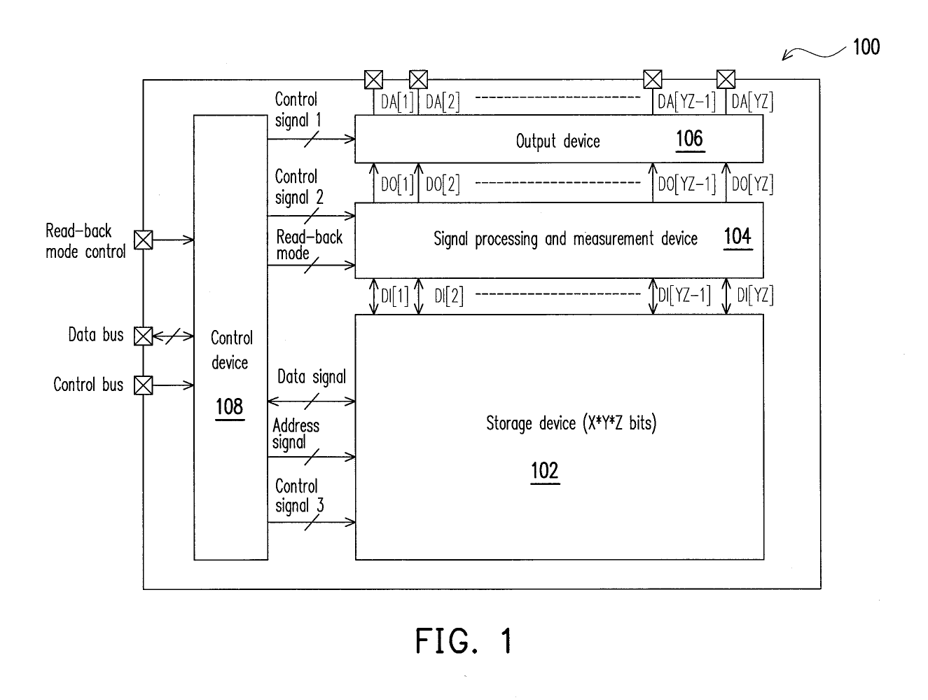

FIG. 1 is a schematic diagram of an embedded storage apparatus according to an embodiment of the present invention. Referring to FIG. 1, the embedded storage apparatus 100 includes a control device 108, a storage device 102, a signal processing and measurement device 104, and an output device 106. When the embedded storage apparatus 100 works in a regular operation mode, the storage device 102 is accessed through the control device 108. When a data is to be written into the storage device 102, the control device 108 obtains the data and the corresponding address from a data bus according to an inputted control signal and then writes the data into the storage device 102. When a data is to be read from the storage device 102, the control device 108 obtains the corresponding address according to a control signal through the data bus and sends the address to the storage device 102, and after that, the control device 108 reads the data from the storage device 102.

The embedded storage apparatus 100 is a chip system with an embedded storage apparatus. The embedded storage apparatus 100 not only provides data storage space but also processes data. When a signal processing device is about to process the data in a storage device, the previously stored data is first read from the storage device 102 by the control device 108 and then processed by the signal processing and measurement device 104. After that, the processed data is sent to the output device 106 so that the signal level and strength thereof can be adjusted. Finally, the data is output through an I/O port.

Before describing the technique provided by the present invention, several factors to be considered in the design of a conventional embedded memory will be first described. A chip system usually does not have too many I/O ports due to the limitations in chip area and chip packaging. In addition, the data bus provided by the control device should be wide enough in order to shorten the data read-back time and reduce the number of data addressing and reading operations during the testing procedure. Even though the testing time can be greatly shortened by increasing the width of the data bus, the number of I/O ports has to be increased and accordingly both the packaging cost and chip area will be increased. Thus, the width of the data bus, the testing time, and the chip area all have to be considered in the design of conventional storage apparatus.

The storage device 102 usually has very different data writing time and data reading time, wherein the reading time is usually longer than the writing time.

However, in the design of embedded storage apparatus, the system clock rate, and accordingly the quantity of data to be processed, has been increased along with the advancement of the fabrication processes. The greater capacity a storage device has, the more I/O ports are disposed. In this case, both the testing time and cost of the entire chip system will be increased if the storage device is still tested by reading data through the control device 108.

A mechanism for shortening the testing time of a storage device in an embedded memory is provided in the present invention. However, the application of the present invention is not limited to the testing of the storage device. Since the number of I/O ports in a chip system is usually much greater than the width of data bus in a storage device, in the present invention, the original path for reading data from the storage device through a control device is changed to outputting the data through other I/O ports of the chip system. If, ideally, every position in the storage device has a corresponding I/O port, the time for reading all the data in the storage device is the same as that for reading the data at one position in a conventional storage device. Accordingly, the testing time of the storage device is greatly shortened.

Different designs of the signal processing and measurement device 104 are provided in the present invention such that the test data can be output through the same I/O ports DA[1], . . . , DA[YZ] instead of from the control device 108. The addresses of data bits in the storage device 102 may be indicated with X, Y, and Z. In the present embodiment, the output terminals of the storage device 102 are DI[1], DI[2], . . . , and DI[YZ], and which are also served as the input terminals of the signal processing and measurement device 104.

The control device 108 has a data bus and a control bus such that the control device 108 can carry out general data access operations on the storage device 102. Besides, the signal processing and measurement device 104 receives a read-back mode control signal (i.e., a mode selection signal) from the control device 108 and controls the operation mode of the signal processing and measurement device 104 according to this read-back mode control signal. The control device 108 generates control signals for respectively controlling the operations of the storage device 102, the signal processing and measurement device 104, and the output device 106, and the signal processing and measurement device 104 is further controlled according to the read-back mode control signal.

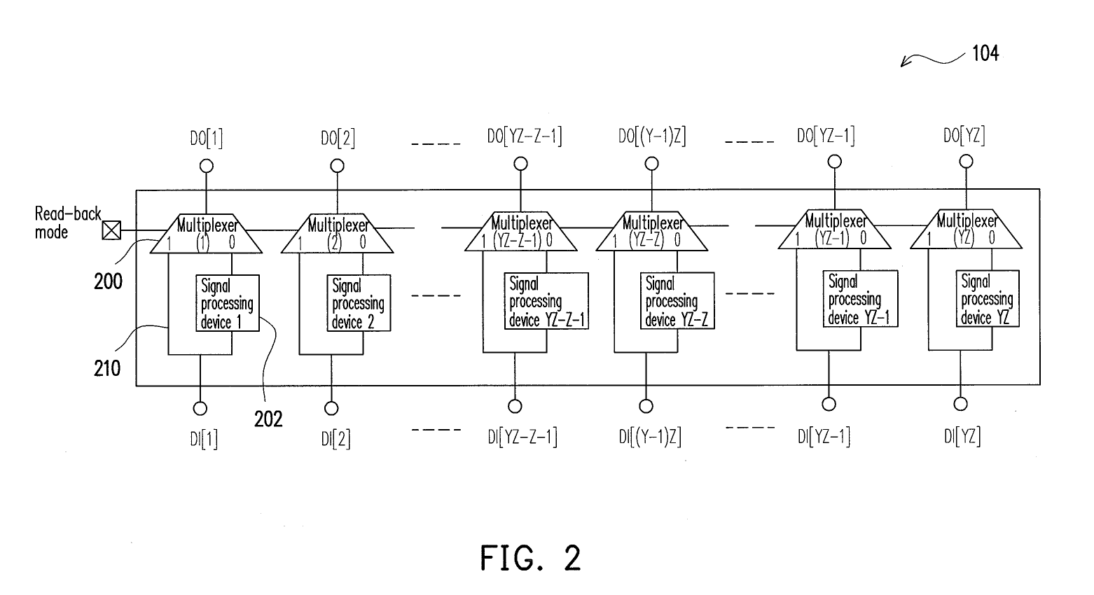

FIG. 2 is a circuit diagram of a signal processing and measurement device according to an embodiment of the present invention. Referring to FIG. 2, the signal processing and measurement device 104 keeps the data reading method of a general embedded storage apparatus and further provides another method for reading data from a storage device, which is, the signal processing and measurement device 104 chooses to output the data in a regular mode or a measurement mode according to a read-back mode control signal.

As shown in FIG. 2, in the signal processing and measurement device 104, each input terminal DI is corresponding to an output unit, wherein the output unit includes a multiplexer 200, a signal processing device 202, and a direct output path 210.

The input terminals DI of the signal processing and measurement device 104 are respectively connected to the output terminals DI of the storage device 102. An input terminal of the multiplexer 200 is connected to the input terminal DI through the direct output path 210. Another input terminal of the multiplexer 200 is connected to the input terminal DI through the signal processing device 202. The signal processing device 202 processes an input data (for example, converts a digital signal into an analog signal) according to the actual requirement. The multiplexer 200 outputs the signal at one of the input terminals to the output terminal DO according to the read-back mode control signal.

For example, when the read-back mode control signal is at a low level (i.e., in the regular mode), the multiplexer 200 chooses to output the signal processed by the signal processing device 202. When the read-back mode control signal is at a high level (i.e., in the measurement mode), the data in the storage device 102 is output from the output terminal DO of the signal processing and measurement device 104 via the direct output path 210.

Referring to FIG. 2 again, the output terminal DO of the signal processing and measurement device 104 is connected to an input terminal of an output device 106. When the output device 106 receives an input signal, it adjusts the level and strength of the signal and sends the adjusted signal to the I/O port DA. It should be noted that the output device 106 is an optional device used for adjusting signal level and strength so that the signal can meet the requirement of a subsequent driving process. Namely, the output device 106 may be omitted in some embodiments.

Through the configurations illustrated in FIG. 1 and FIG. 2, many I/O ports can be used as data read-back output terminals during the testing procedure such that all the test data in the storage device 102 can be quickly read. Since the I/O ports used herein are also used in the regular operation mode, no additional I/O port is needed. The memory capacity and the number of I/O ports will be ever increased along with the development of chip system, and the technique provided by the present embodiment is suitable for such chip systems.

The number of I/O ports illustrated in FIG. 2 is only an example. In the read-back mode, based on the concept of directly outputting the test data from the storage device through the I/O ports, the read-back test data may be further adjusted to fully utilize the output terminals of the I/O ports.

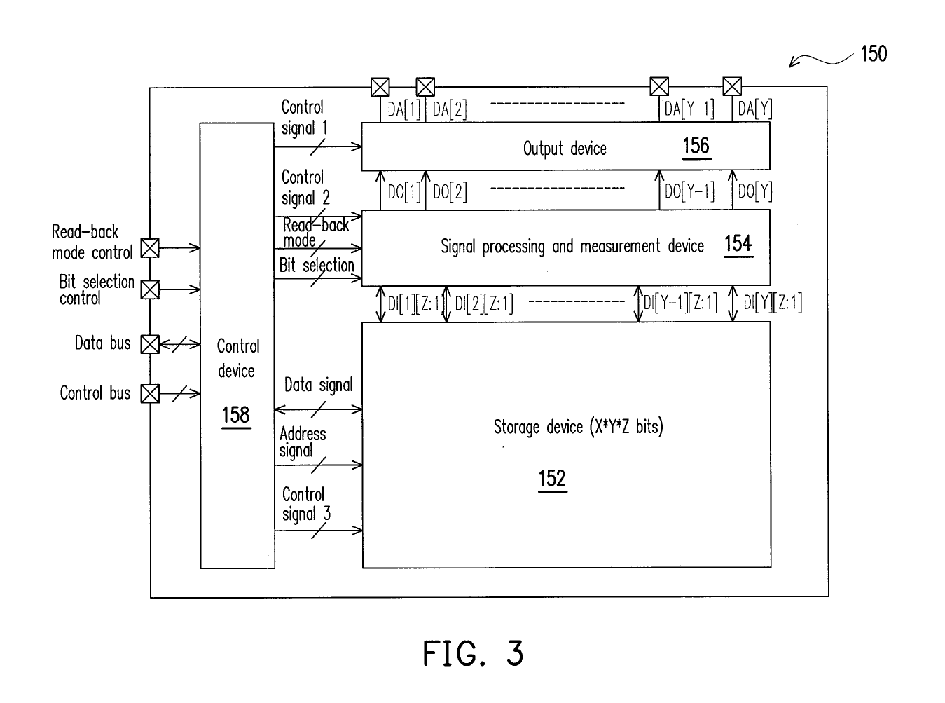

FIG. 3 is a schematic diagram of an embedded storage apparatus according to another embodiment of the present invention. Referring to FIG. 3, in another embodiment of fast measurement, the embedded storage apparatus 150 includes a control device 158, a storage device 152, a signal processing and measurement device 154, and an output device 156. Compared to the embodiment illustrated in FIG. 1, the signal processing and measurement device 154 further generates a plurality of bit selection signals. The control device 158 controls the signal processing and measurement device 154 according to the external bit selection signals. The purpose of the bit selection signals will be described herein. When there is no enough I/O ports for outputting an entire row of bit data in the storage device 102 at once, the control device 158 can switch from time to time through a time division multiplexing (TDM) technique at the same I/O port according to the bit selection signals to output different testing bit data, and eventually, all the bit data in the row can still be collected. The signal processing and measurement device 154 can be changed appropriately if this technique is adopted.

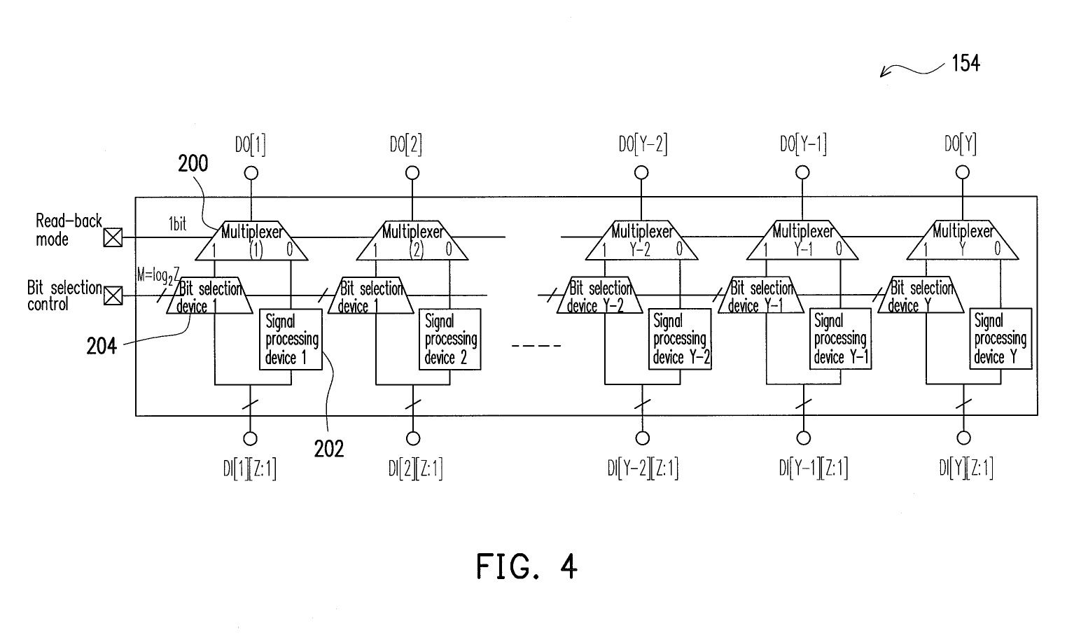

FIG. 4 is a circuit diagram of a signal processing and measurement device according to another embodiment of the present invention. Referring to FIG. 4, the signal processing and measurement device 154 includes input signals DI[1][Z:1]-DI[Y][Z:1], wherein Y represents the number of words, and Z represents the number of bits. Each of the output terminals DO[1]-DO[Y] is used for outputting an output signal of one word. Herein one word has Z bits, wherein Z is 8. However, the value of Z is not limited to 8. Each output terminal is corresponding to an output unit, wherein the output unit includes a multiplexer 200, a bit selection device 204, and a signal processing device 202. Every time the input terminal DI receives a digital word data having Z bits from the storage device 152 and transmits the digital word data respectively to the bit selection device 204 and the signal processing device 202. The bit selection device 204 and the signal processing device 202 are respectively connected to the two input terminals of a multiplexer. One of the two signals is transmitted to the output terminals DO according to a read-back mode control signal. In the present embodiment, the number of the output terminals DO is reduced to Y.

In the regular operation mode, the signal processing and measurement device 154 is set to a regular mode when the read-back mode control signal is at a low level. After a Z-bit data is input respectively through the input terminals DI and processed by the signal processing device 202, the signal is respectively transmitted to the output terminals DO through the corresponding multiplexers 200. Herein since the input data is a Z-bit digital data, the signal processing device 202 converts the Z-bit digital data into a single analog signal. The operation of the chip system in the regular mode is the same as that of the signal processing and measurement device in the first embodiment.

The signal processing and measurement device 154 is set to a measurement mode when the read-back mode control signal is at a high level. Herein the input signals DI[1][Z:1]-DI[Y][Z:1] respectively pass through the bit selection device 204, and the bit selection device 204 sequentially outputs the bit data according to bit selection signals. Herein different bit data is sequentially transmitted to the output terminal of the bit selection device 204 through M control lines, wherein M=log₂Z.

For example, the bit selection device 204 determines the bit data DI[1][Z:1] to be transmitted to the output terminal DO[1] according to a bit selection signal. Taking a data having 8 bits (i.e., an input signal DI[1][8:1]) as an example, the bits DI[1][1], DI[1][2], . . . , and DI[1][8] in the data are sequentially output to the output terminal DO[1] according to bit selection signals, and a complete word data is collected after 8 eight times of data read-back.

Through the control of the bit selection lines, the first bit selection device 204 to the Y^{th} bit selection device 204 sequentially transmit the bit data to the output terminals DO[1]-DO[Y] respectively through the multiplexers 1-Y without performing any signal processing. The problem of insufficient I/O ports in an embedded storage apparatus for outputting an entire row of bit data in a storage device is resolved through the TDM technique. Besides, the many I/O ports in the chip system are used for speeding up the read-back operation of the storage apparatus, so as to shorten the testing time of the storage apparatus.

Thereafter, the output device 156 performs signal processing (for example, increases the voltage level of the signal) corresponding to subsequent operations after the signal processing and measurement device 154.

It should be noted that when the system is in a data read-back state of the testing mode, even though the signal output from the I/O port is analog signal, it is corresponding to a bit data therefore has only two states. Thus, the two states of the bit data should be recognized and determined through a subsequent sensing mechanism, and which won't affect the regular operations. In other words, in the embedded storage apparatus 150, data does not have to be output by the output device 156. Instead, the data may also be directly output by the signal processing and measurement device 154 so that external data testing can be carried out.

As to the overall operation mechanism, the control device, storage device, signal processing and measurement device, and output device of the embedded storage apparatus may operate as described below.

The control device generates control signals for controlling the storage device to access data, the control signals for controlling the signal processing and measurement device to access the data output by the storage device, and the control signals for determining the output configuration of the output device.

The storage device determines the address to be accessed according to the signal input by the control device, wherein the read or write action is determined by the input signal of the control device. When data is to be read from the storage device, the control device sends the corresponding address to the storage device and reads the data. When data is to be written into the storage device, the control device sends the data and address to be written to the storage device and writes the data to the corresponding address.

The signal processing and measurement device receives a signal read by the storage device and determines the operation mode of the circuit according to a read-back mode control signal. When the read-back mode control signal is at a low level, the signal processing and measurement device operates in a regular mode, and the data read from the storage device is first processed by the signal processing device and then sent to the input terminal of the output device through a multiplexer.

When the read-back mode control signal is at a high level, the signal processing and measurement device operates in a measurement mode, and the data read from the storage device is directly sent to the input terminal of the output device through the multiplexer. In this technique, based on the fact that the number of I/O ports is far greater than the width of the data bus, the data read from the storage device is directly sent to the output device to be output so that a large quantity of data can be read at once. Thereby, the testing time of the storage apparatus is further shortened without affecting the operation of the circuit.

The output device receives the output signal of the signal processing and measurement device as its input signal, and the output device intensifies the signal received from the signal processing and measurement device and then outputs the intensified signal through the I/O port, so that the driving capability of the circuit can be improved.

The storage device is not limited to any particular type of storage device. In the present invention, the I/O ports are used both in the regular operation of the storage device and in other fast data measurement functions. During the testing procedure, a data can be directly output through the I/O ports without being processed. As to the direct data output, the bit data can be directly output through TDM according to the number of output terminals of the I/O ports. In addition, the sequence in which the bit data is output can be determined according to the actual requirement.

As described above, the present invention provides an embedded storage apparatus. To achieve a fast measurement effect, the read-back path of a storage device is changed by adopting a signal processing and measurement device so that the data is output through I/O ports instead of a data bus, wherein the number of the I/O ports is much greater than the width of the data bus. During the testing procedure, since multiple data can be read at once, both the testing time and cost are shortened.

In addition, according to the present invention, the read-back path of a storage device is changed by adopting a signal processing and measurement device, so that the I/O ports of the chip system can be fully utilized and no additional lead is to be disposed.

Moreover, according to the present invention, a system chip can quickly test a storage device through the technique provided by the present invention, and more testing programs can be performed if the testing is carried out within the same testing time. Thus, the test can cover a more complete range.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An embedded storage apparatus, comprising:
a control unit, for outputting a plurality of signals, wherein the signals comprise a mode selection signal and a plurality of control signals;
a storage unit, controlled by the control unit to read a data from a predetermined address, wherein the storage unit has a plurality of output terminals; and
a signal processing and measurement unit, having a plurality of input terminals and a plurality of output terminals, wherein the input terminals are connected to the output terminals of the storage unit, the signal processing and measurement unit reads the data from the input terminals and determines whether to perform a predetermined processing on the data according to the mode selection signal, and the signal processing and measurement unit outputs the data through the output terminals.

2. The embedded storage apparatus according to claim 1, wherein the input terminals of the signal processing and measurement unit and the output terminals have a same number and are respectively corresponding to each other.

3. The embedded storage apparatus according to claim 2, wherein the signal processing and measurement unit comprises:
a plurality of signal processing devices, wherein each of the signal processing devices is corresponding to one of the output terminals, receives the data from the corresponding output terminal, and performs the predetermined processing on the data;
a plurality of multiplexers, wherein each of the multiplexers is corresponding to one of the output terminals and comprises:
a first input terminal, for directly receiving the data from the storage unit; and
a second input terminal, coupled to one of the signal processing devices, for receiving the processed data;
wherein the multiplexer outputs the data at the first input terminal or the second input terminal according to the mode selection signal.

4. The embedded storage apparatus according to claim 3, wherein the multiplexers output the data at the first input terminals when the mode selection signal is activated, otherwise the multiplexers output the data at the second input terminals.

5. The embedded storage apparatus according to claim 1, wherein every fixed number of the input terminals of the signal processing and measurement unit are grouped into an output terminal group corresponding to one of the output terminals.

6. The embedded storage apparatus according to claim 4, wherein the signal processing and measurement unit comprises:
a plurality of output units, wherein each of the output units is disposed corresponding to one of the output terminals and comprises:
a multiplexer, having a first input terminal, a second input terminal, and an output terminal, wherein the output terminal is one of the output terminals of the signal processing and measurement unit, the multiplexer outputs data at the first input terminal or the second input terminal according to the mode selection signal;
a bit selection unit, having an output terminal and a group input terminal, wherein the output terminal is connected to the first input terminal of the multiplexer, the group input terminal is connected to the corresponding output terminal of the storage unit, and the bit selection unit sequentially outputs data at the group input terminal to the output terminal according to a bit selection signal generated by the control unit; and
a signal processing unit, having an output terminal and a group input terminal, wherein the group input terminal is connected to the corresponding output terminal of the storage unit, and the signal processing unit converts the data into a single analog signal and outputs the single analog signal from the output terminal.

7. The embedded storage apparatus according to claim 6, wherein a number of the group input terminals is a number of bits in a word data.

8. The embedded storage apparatus according to claim 6, wherein the multiplexers output the data at the first input terminals when the mode selection signal is activated, otherwise the multiplexers output the data at the second input terminals.

9. The embedded storage apparatus according to claim 1, wherein the storage unit further comprises a plurality of data signal terminals connected to the control unit, such that the control unit directly writes data into or reads data from the storage unit.

10. The embedded storage apparatus according to claim 1 further comprising an output unit connected to the output terminals of the signal processing and measurement unit, and the output unit outputs an intensified signal according to one of the control signals.

11. The embedded storage apparatus according to claim 1, wherein the control unit activates the mode selection signal according to a read-back mode control signal.

12. The embedded storage apparatus according to claim 1, wherein the mode selection signal is activated in a testing mode so as to control the signal processing and measurement unit.

13. A test method adaptable to the embedded storage apparatus in claim 1, the test method comprising:
writing a test data from the control unit into the storage unit;
activating the mode selection signal, directly outputting the test data through the output terminals, and transmitting the test data to an output port through the signal processing and measurement unit.

14. The test method according to claim 13 further comprising sensing the test data output by the signal processing and measurement unit to determine a bit content.

15. A test method adaptable to an embedded storage apparatus, wherein the embedded storage apparatus comprises a storage unit and a signal processing unit, the storage unit has a plurality of output terminals, and in a regular operation mode, the signal processing unit processes a data output by the storage unit and outputs the processed data through an output port, the test method comprising:
writing a test data into the storage unit; and
directly outputting the unprocessed test data through the output port via an output path of the signal processing unit.

16. The storage apparatus testing method according to claim 15 further comprising sensing the test data output by the signal processing unit to determine a bit content.
